(19) United States
(12) Patent Application Publication
(10) Pub. No.: US 2026/0128568 A1
(43) Pub. Date: May 7, 2026

(54) METHOD FOR PRODUCING A SEMICONDUCTOR LASER AND SEMICONDUCTOR LASER

(71) Applicant: ams-OSRAM International GmbH, Regensburg (DE)

(72) Inventors: Jelena Ristic, Regensburg (DE); Hubert Halbritter, Dietfurt (DE)

(21) Appl. No.: 19/116,246

(22) PCT Filed: Sep. 14, 2023
(86) PCT No.: PCT/EP2023/075231

§ 371 Date: Mar. 27, 2025

(30) Foreign Application Priority Data
Sep. 29, 2022 (DE) 102022125146.2

(51) Int. Cl. H01S 5/183; H01S 5/042

(52) U.S. Cl. CPC H01S 5/18344; H01S 5/0421

(57) ABSTRACT

In an embodiment a method includes providing a semiconductor body having a first region of a first conductivity type, a second region and an active region for producing electromagnetic radiation arranged between the first and the second region, forming a mask on the second region, forming a hole in the mask so that a surface of the second region is exposed; and growing a mesa structure of a semiconductor material on the exposed surface of the second region in the hole of the mask, wherein the mesa structure is at least partially of a second conductivity type being different from the first conductivity type, and wherein a height of the mesa structure is at most 50 nm.

### CROSS-REFERENCE TO RELATED APPLICATIONS

This patent application is a national phase filing under section 371 of PCT/EP 2023/075231, filed Sep. 14, 2023, which claims the priority of German patent application no. 102022125146.2, filed Sep. 29, 2022, each of which is incorporated herein by reference in its entirety.

### TECHNICAL FIELD

The present disclosure relates to a method for producing a semiconductor laser and to a semiconductor laser.

### SUMMARY

Embodiments provide an improved method for producing a semiconductor laser, for example, a method with which particularly small semiconductor lasers can be produced. Further embodiments provide a semiconductor laser which can be produced with this method.

First, the method for producing a semiconductor laser is specified.

According to at least one embodiment, the method comprises a step in which a semiconductor body is provided. The semiconductor body has a first region of a first conductivity type, a second region and an active region for producing electromagnetic radiation arranged between the first and the second region.

The semiconductor body is based, for example, on a III-V compound semiconductor material. The semiconductor material may be a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs or AlₙIn₁₋ₙ₋ₘGaₘAsP, where 0≤n≤1, 0≤m≤1, and m+n≤1, respectively. The semiconductor body may have dopants, as well as additional components. For simplicity, however, only the essential constituents of the crystal lattice of the semiconductor body, i.e. Al, As, Ga, In, N or P, are indicated, even if these may be partially replaced and/or supplemented by small amounts of additional substances. Preferably, the semiconductor body is based on AlₙIn₁₋ₙ₋ₘGaₘN.

The active region, also referred to as active layer, includes, for example, at least one pn junction and/or at least one quantum well structure in the form of a single quantum well, SQW for short, or in the form of a multi-quantum well structure, MQW for short. The active region is, for example, epitaxially grown on the first region.

The active region can, for example, generate radiation in the blue or green or red spectral range or in the UV range or in the IR range during intended operation.

The first region may be epitaxially grown on a growth substrate. The first region may comprise a plurality of epitaxially grown and differently composed layers. The first conductivity type is, for example, electron conduction. That is, the first region may be n-doped. The first region may adjoin the active region.

The second region may be epitaxially grown on the active region. For example, the second region comprises one epitaxially grown layer or a plurality of epitaxially grown and differently composed layers. At least one layer of the second region may be of a second conductivity type which is different from the first conductivity type. For example, the second conductivity type is hole conduction. Alternatively, the second region may be undoped. For example, the second region adjoins the active region.

According to at least one embodiment, the method comprises a step in which a mask is formed on the second region. For example, the mask is formed by disposing a mask material onto the second region and then structuring the mask material by means of photolithography. Particularly, the mask is formed on a side of the second region facing away from the active region and the first region.

According to at least one embodiment, a hole is formed in the mask. A surface of the second region is exposed in the hole. Particularly, the exposed surface is a surface facing away from the active region. In top view onto the mask, the exposed portion of the second region in the hole covers a portion of the active region and a portion of the first region.

The mask may comprise a plurality of holes which are laterally spaced from each other and, in each of the holes, the surface of the second region is exposed. All features disclosed in connection with one hole are also disclosed for all other holes in the mask.

A lateral direction is herein defined as a direction parallel to a main extension plane of the semiconductor body or parallel to the main extension plane of the active region, respectively. A vertical direction is herein defined as a direction perpendicular to the mentioned main extension plane(s).

According to at least one embodiment, the method comprises a step of growing, e.g. epitaxially growing, a mesa structure of a semiconductor material on the exposed surface of the second region in the hole of the mask. The mesa structure is at least partially of the second conductivity type, which is different from the first conductivity type. The mesa structure may be grown directly on the exposed surface.

For example, the mesa structure comprises at least one layer of a semiconductor material being of the second conductivity type or the mesa structure is entirely of the second conductivity type. The mesa structure is, in particular, based on the same semiconductor material as the semiconductor body, e.g. AlₙIn₁₋ₙ₋ₘGaₘN.

In other words, the mesa structure is formed by regrowth on the semiconductor body. A corresponding mesa structure may be formed in each hole. The mesa structure is, in particular, a protrusion of semiconductor material protruding from the surface of the second region in a direction away from the active region. The height of the mesa structure, measured in vertical direction, is, for example, at most 1 μm. Lateral extensions of the mesa structure may be at most 15 μm or at most 5 μm. In top view onto the surface of the second region, the mesa structure may have the form of a circle or a rectangle. In particular, the shape and/or the lateral extensions of the mesa structure is defined by the shape and/or the lateral extensions of the hole in the mask. Especially, the shape and/or the lateral extensions of the mesa structure equals the shape and/or lateral extensions of the hole.

The mesa structure is, for example, configured to confine and guide charge carriers, like holes, from a contact element to the active region. That is, during operation of the semiconductor laser, charge carriers flow through the mesa structure(s).

In at least one embodiment, the method for producing a semiconductor laser comprises:
providing a semiconductor body having a first region of a first conductivity type, a second region and an active region for producing electromagnetic radiation arranged between the first and the second region;
forming a mask on the second region, wherein a hole is formed in the mask in which a surface of the second region is exposed;
growing a mesa structure of semiconductor material on the exposed surface of the second region in the hole of the mask, wherein the mesa structure is at least partially of a second conductivity type being different from the first conductivity type.

In many semiconductor lasers, for example in VCSELs, a mesa structure, also simply referred to as mesa, needs to be formed, e.g. on the p-side. This is normally done via mesa etching (RIE etching). This etching causes damage, lateral and in depth. Lateral damage affects the lateral sides causing higher resistivity, non-radiative recombination and losses. Damage in depth, e.g. into the active region, causes electrical losses, lower IQE and leads to degradation and aging. Additionally, the roughness caused by the etching might cause scattering and optical losses.

Therefore, current semiconductor lasers are often formed by MESA obtained with Reactive Ion Etching (i.e. RIE) which requires thick second region (e.g. p-side) which on the other hand results in higher optical losses (higher absorption) and higher electrical losses (higher Rf). This limits device design in terms of optimization and later fabrication and also limits device performance (WPE).

The above-mentioned compromise can be maintained as long as the semiconductor laser and the corresponding second region are comparably large. However, as the damage caused by the mesa etching is in the range of at least 25 nm, such damage is no longer acceptable when the size of the semiconductor laser, particularly the thickness of the semiconductor body, is significantly reduced, for example to the theoretical limit for the resonator length.

Therefore, the inventors developed a method which avoids such damage and enables a particularly thin mesa structure. This is achieved by growing the mesa structure instead of mesa etching. The (re)growth creates defect-free mesa structures and leaves the semiconductor body, particularly the active region below the mesa structure, free of damage. The method allows very thin semiconductor lasers down to the theoretical limit to be produced.

According to at least one embodiment, the semiconductor laser is a vertical cavity surface emitting laser, VCSEL for short.

According to at least one embodiment, after the growth of the mesa structure, a contact layer is arranged on the mesa structure. The contact layer is electrically conductive. Particularly, the contact layer is transparent for the radiation produced by the active region. The contact layer is, for example, of a transparent conductive oxide, like ITO.

The contact layer may be applied as a contiguous layer, without interruptions, covering the top side of the mesa structure facing away from the active region and, optionally, the lateral sides of the mesa structure, which delimit the mesa structure in lateral direction. The contact layer may also cover areas of the second region laterally next to the mesa structure. The contact layer may be in direct mechanical and electrical contact with the semiconductor material of the mesa structure.

According to at least one embodiment, after the growth of the mesa structure, a contact element is arranged on the contact layer. The contact element is, for example, formed of metal. For example, the contact element comprises Au. The contact element may be brought in direct electrical and mechanical contact with the contact layer. For example, the electrical contact is formed laterally next to the mesa structure.

According to a further embodiment, after the growth of the mesa structure, a Bragg mirror is arranged on the mesa structure. The Bragg mirror may be applied after the application of the contact layer and/or before the application of the contact element. In top view onto the surface of the second region, the Bragg mirror may completely cover the mesa structure. For example, the Bragg mirror is brought in direct mechanical contact with the contact layer.

According to at least one embodiment, a further mirror, e.g. a Bragg mirror, is formed on a side of the first region facing away from the active region. The Bragg mirror and the further mirror form a resonator for producing laser radiation. The first region may be grown on the further mirror.

According to at least one embodiment, the height of the mesa structure, measured in vertical direction, is at most 50 nm or at most 30 nm or at most 20 nm. The thickness of the second region, measured in vertical direction, is, for example, at most 300 nm or at most 100 nm.

According to at least one embodiment, selective area growth is used for growing the mesa structure so that less and/or polycrystalline semiconductor material is grown or deposited on the mask laterally next to the hole than in the hole. For example, no semiconductor material is deposited or grown on the mask laterally next to the hole. The choice of the growth conditions and/or of the material of the mask influences how much semiconductor material is grown or deposited on the mask. For example, the mask is formed of silicon dioxide (SiO₂).

According to at least one embodiment, during the growth of the mesa structure, the semiconductor material is also deposited or grown on the mask laterally next to the hole.

According to at least one embodiment, the semiconductor material on the mask laterally next to the hole is removed afterwards. For example, the semiconductor material laterally next to the hole is removed together with the mask laterally next to the hole or together with a part of the mask laterally next to the hole.

According to at least one embodiment, a top side of the mesa structure facing away from the active region has a higher doping concentration than the surface of the second region facing away from the active region in the area laterally next to the mesa structure. For example, the doping concentration at the top side of the mesa structure is at least 10 times or at least 100 times or at least 1000 times larger than at the surface of the second region.

Furthermore, the top side of the mesa structure may have a higher doping concentration than the lateral sides of the mesa structure.

According to at least one embodiment, the contact layer is applied directly onto the second region in the area laterally next to the mesa structure. Thus, the contact layer adjoins the second region in this area. This means that the mask is removed beforehand.

Due to the surface of the second region having a lower doping concentration than the top side of the mesa structure, a dielectric/isolating intermediate layer between the contact layer and the second region is not necessary as the electrical contact between the contact layer and the second region is inferior compared to the electrical contact between the mesa structure and the contact layer.

Alternatively, the surface of the second region could have the same or similar doping concentration as the top side of the mesa structure. “Similar” means, e.g., with a deviation of at most 50% or at most 10%. In this case an electrically isolating layer should be used between contact layer and the second region.

According to at least one embodiment, the exposed surface of the second region is formed of an undoped spacer layer. The spacer layer adjoins the active region, for example. The spacer layer may be formed of unintentionally doped semiconductor material. For example, the doping concentration or free charge carrier concentration, respectively, in the spacer layer is at most 1017 cm−3 . The spacer layer prevents, for example, diffusion of second type dopants, like magnesium, into the active region. For example, the thickness of the spacer layer is at least 50 nm and/or at most 250 nm.

This embodiment has, inter alia, the technical advantage that the contact layer may then be applied directly onto the second region in the area laterally next to the mesa structure without an intermediate dielectric layer. This is possible, as the electrical contact between the contact layer and the undoped semiconductor material of the spacer layer is low.

According to a at least one embodiment, the exposed surface of the second region is formed of a blocking layer for blocking charge carriers of the first type, which are, for example, electrons. The blocking layer may be of the second conductivity type. For example, the blocking layer is doped with second type dopants. The doping concentration is, for example, at least 1017 cm−3 and at most 1020cm−3 . For example, the blocking layer comprises InxAlyGa1-x-yN with y≥0,1 or y≥0.15 or y≥0.2.

Also here, a technical advantage is, inter alia, that the contact layer can be applied directly onto the second region in the area laterally next to the mesa structure without an intermediate dielectric layer. This is possible as the electrical contact between the contact layer and the low-doped semiconductor material of the blocking layer is low.

According to at least one embodiment, the exposed surface of the second region is formed of a highly doped layer having a doping concentration of at least 1019 cm−3 or at least 1020 cm−3 . The dopants are, in particular, second type dopants.

The surface of the second region laterally next to the mesa structure has, in particular, the same composition and doping concentration as the surface of the second region in the hole before the growth of the mesa structure.

In the case that the surface of the second region exposed in the hole is formed by the undoped spacer layer, the mesa structure may be grown such that it comprises a blocking layer as specified above, and a highly doped layer as specified above. The blocking layer is then formed between the highly doped layer and the spacer layer. For example, the mesa structure then consists of the highly doped layer and the electron blocking layer.

In the case that the surface of the second region exposed in the hole is formed by the electron blocking layer, the mesa structure may be grown such that it comprises a highly doped layer as specified above. For example, the mesa structure than consists of the highly doped layer or highly doped layers. In the second region, a spacer layer as specified above may be arranged between the blocking layer and the active region.

In the case that the surface of the second region exposed in the hole is formed by a highly doped layer, the mesa structure may be grown such that it also consists of highly doped semiconductor material with a doping concentration of at least 1019 cm−3 . The second region of the semiconductor body may then comprise a spacer layer as specified above, a blocking layer as specified above and the highly doped layer in this order when starting from the active region.

According to at least one embodiment, the mask comprises a dielectric layer or consists of a dielectric layer. The material of the dielectric layer is, for example, silicon dioxide, SiO2. The dielectric layer may have a thickness of at most 5 nm or may be a monolayer. For example, the dielectric layer is deposited on the second region by ALD.

According to at least one embodiment, the dielectric layer remains in the final semiconductor laser in order to supress or prevent a current flow in the second region laterally next to the mesa structure. The dielectric layer shall, in particular, supress or prevent a current flow between the contact element/contact layer and the second region laterally next to the mesa structure and shall force the current to flow through the mesa structure. The dielectric layer may form an optical aperture of the semiconductor laser. The mesa structure is formed in the hole of the dielectric layer.

According to at least one embodiment, the mask is removed after the growth of the mesa structure. For example, a dielectric layer is then arranged laterally next to the mesa structure. When removing the mask, the semiconductor material on the mask laterally next to the hole may be removed together with the mask. The dielectric layer arranged after removal of the mask may be the same dielectric layer as specified above. The dielectric layer may be applied such that it adjoins the lateral sides of the mesa structure. The top side of the mesa structure is not covered by the dielectric layer.

According to at least one embodiment, the mask comprises a layer of a 2-dimensional material. For example, the mask consists of the layer of a 2-dimensional material. The layer of the 2-dimensional material has, for example, a thickness of at least 2 nm and/or at most 60 nm, particularly between 2 nm and 5 nm.

According to at least one embodiment, the layer of the 2-dimensional material is removed after the mesa structure has been grown.

A 2-dimensional material is herein understood as a material which forms ionic bonds or covalent bonds only in two dimensions. In the third dimension, the different layers of the 2-dimensional material are bonded together by Van-der-Waals interaction. Thus, the 2-dimensional material comprises loosely bonded 2-dimensional sublayers stacked above each other. The 2-dimensional sublayers extend, for example, in the lateral directions. Such a material is particularly suitable if it should be removed after the growth of the mesa structure. Examples of such a 2-dimensional material are graphite/graphene and hexagonal boron nitride (hNB).

By way of example, the mask comprises a dielectric layer and a layer of a 2-dimensional material. The dielectric layer may be arranged between the layer of the 2-dimensional material and the second region. Thus, the layer of the 2-dimensional material may protect the dielectric layer. After the growth of the mesa structure, the layer of the 2-dimensional material, if applicable with semiconductor material thereon, may be removed and the dielectric layer may remain in the final semiconductor laser.

According to at least one embodiment, the mesa structure is grown such that it vertically projects beyond the mask. For example, the mesa structure projects beyond the mask by at least 5 nm or at least 10 nm.

According to at least one embodiment, the mesa structure is grown such that it terminates flush with the mask in vertical direction.

According to at least one embodiment, the mesa structure is grown such that it tapers in vertical direction away from the active region. That is, the lateral extension/diameter of the mesa structure becomes smaller when moving in vertical direction away from the active region. For example, at the top side of the mesa structure, i.e. in the area of the mesa structure most distant from the active region, the lateral extension of the mesa structure is at most 75% or at most 50% of the lateral extension in the area of the mesa structure adjoining the second region, i.e. in the area of the mesa structure closest to the active region.

According to at least one embodiment, the mesa structure is grown such that it tapers in vertical direction towards the active region. That is, the lateral extension/diameter of the mesa structure becomes smaller when moving in vertical direction towards the active region. For example, in the area of the mesa structure adjoining the second region, the lateral extension of the mesa structure is at most 75% or at most 50% of the lateral extension of the mesa structure at the top side.

Next, the semiconductor laser is specified. The semiconductor laser may, in particular, be produced with the method according to any of the embodiments described herein. Therefore, all features disclosed for the method are also disclosed for the semiconductor laser and vice versa.

In at least one embodiment, the semiconductor laser comprises a semiconductor body having a first region of a first conductivity type, a second region and an active region for producing electromagnetic radiation arranged between the first and the second region. The semiconductor laser further comprises a mesa structure of semiconductor material which is grown on the second region and which is free of traces of an etching process. The mesa structure is at least partially of a second conductivity type, said second conductivity type being different from the first conductivity type.

The second region, together with the mesa structure, may constitute a layer sequence having a spacer layer, a blocking layer and a highly doped layer arranged in this order when starting from the active region. The second region and/or the mesa structure are, for example, at least partially p-doped. The first region is, for example, n-doped. The second region together with the mesa structure may have a thickness of at most 2·(lambda/2) or at most 1.5·(lambda/2) or at most (lambda/2) or at most 0.5·(lambda/2). 0.5·(lambda/2) is theoretical minimum thickness when considering maximum standing waves in quantum wells. Lambda is the modal value or the average value of the wavelength emitted by the active region.

“Free of traces of an etching process” means, in particular, that lateral surfaces of the mesa structure are free of remnants of an etching agent. Also the second region in the area laterally next to the mesa structure may be free of traces of an etching process. For example, the lateral surfaces is free of Argon. Chlorine, Oxygen, Boron and/or GaO remnants.

According to at least one embodiment, the semiconductor laser is a VCSEL.

According to at least one embodiment, a dielectric layer is arranged laterally next to the mesa structure on the second region. For example, the dielectric layer covers every part of the second region on which no mesa structure is grown. The mesa structure may project beyond the dielectric layer or may terminate flush with the dielectric layer in vertical direction.

According to at least one embodiment, the semiconductor laser further comprises a contact layer which is arranged on the mesa structure and in the area laterally next to the mesa structure. For example, the contact layer adjoins the dielectric layer or the second region in the area laterally next to the mesa structure. The contact layer is in electrical contact with the mesa structure. For example, the contact layer is a contiguous layer, without interruptions, which is in direct mechanical contact with at least a top side of the mesa structure facing away from the active region.

According to at least one embodiment, a contact element is arranged on the contact layer and is in electrical contact with the contact layer.

According to at least one embodiment, a Bragg mirror is arranged on the mesa structure. For example, the contact layer is arranged vertically between the mesa structure and the Bragg mirror. In top view, the Bragg mirror may completely cover the mesa structure.

### BRIEF DESCRIPTION OF THE DRAWINGS

Hereinafter, the method for producing a semiconductor laser and the semiconductor laser will be explained in more detail with reference to the drawings on the basis of exemplary embodiments. The accompanying figures are included to provide a further understanding. In the figures, elements of the same structure and/or functionality may be referenced by the same reference signs. It is to be understood that the embodiments shown in the figures are illustrative representations and are not necessarily drawn to scale. In so far as elements or components correspond to one another in terms of their function in different figures, the description thereof is not repeated for each of the following figures. For the sake of clarity, elements might not appear with corresponding reference symbols in all figures.

FIGS. 1 to 4 show different positions in a first exemplary embodiment of the method;

FIG. 5 shows a first exemplary embodiment of the semiconductor laser;

FIGS. 6 to 9 show different positions in a second exemplary embodiment of the method, ;

FIG. 10 shows a second exemplary embodiment of the semiconductor laser;

FIGS. 11 to 16 show different positions in a third exemplary embodiment of the method;

FIGS. 17 to 21 show different positions in a fourth exemplary embodiment of the method;

FIGS. 22 to 27 show different positions in a fifth exemplary embodiment of the method; and

FIGS. 28 to 30 show further exemplary embodiments of the semiconductor laser.

### DETAILED DESCRIPTION OF ILLUSTRATIVE EMBODIMENTS

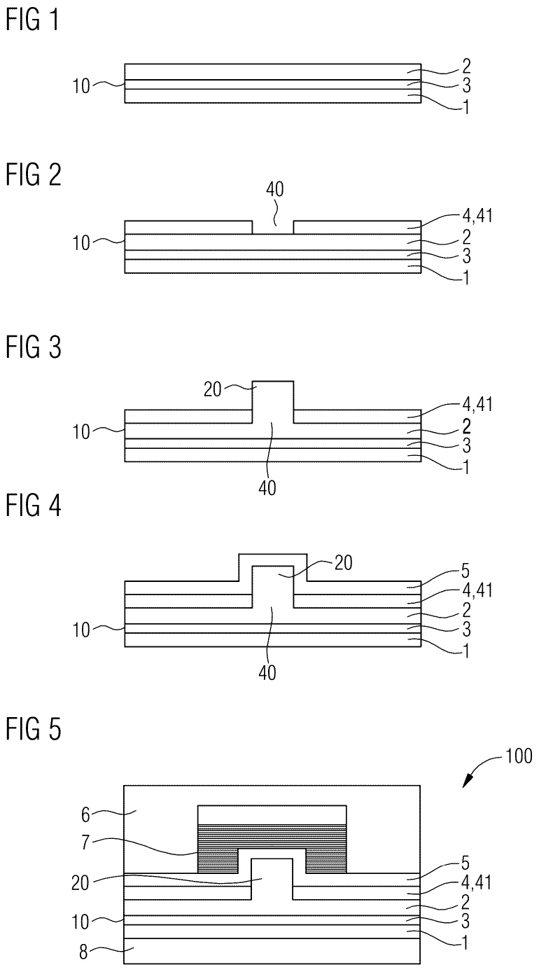

The first exemplary embodiment of the method is shown in FIGS. 1 to 4. In the position of FIG. 1, a semiconductor body 10 with a first region 1, a second region 2 and an active region 3 arranged between the first 1 and the second 2 region is provided. The semiconductor body 10 is, for example, based on AlnGamIn1-n-mN. The first region 1 is of a first conductivity type. The second region 2 may at least partially be of a second conductivity type or may be undoped.

In the following, it is assumed that the first conductivity type is electron conduction and, accordingly, the first region 1 is n-doped. Consequently, the second conductivity type is hole conduction, and the corresponding doping type is p-doping. However, this is just an example and the opposite case, where the first conductivity type is hole conduction and the second conductivity type is electron conduction, is also possible.

The first region 1 may comprise a plurality of semiconductor layers epitaxially grown on top of each other and having different compositions. The active region 3 may be epitaxially grown on the first region 1. The second region 2 may be epitaxially grown on the active region 3. The surface of the second region 2 facing away from the active region 3 may be formed by an undoped spacer layer or doped electron blocking layer or a highly doped layer having a doping concentration of at least 1019 cm−3 .

The active region 3 comprises, for example, a multi-quantum well structure, MQW for short, and is configured to produce electromagnetic radiation during operation. For example, the active region 3 is configured to produce electromagnetic radiation in the blue, green, red or UV spectral range.

In the position of FIG. 2, a mask 4 having a hole 40 is formed on the second region 2. Inside the hole 40, the surface of the second region facing away from the active region 3 is exposed. The mask 4 is, for example, of dielectric material, like SiO2.

For producing the mask 4, a layer of the mask material may have been applied to the surface of the second region 2 and may then have been structured by means of photolithography.

In the position of FIG. 3, a mesa structure 20 of semiconductor material is epitaxially grown in the hole 40 of the mask 4. Due to the material of the mask 4, the semiconductor material used for the epitaxial growth has only deposited/grown in the hole 40 (selective area growth) and not on the mask 4 laterally next to the hole 40.

The semiconductor material of the mesa structure 20 is of the same type as the semiconductor body 10, i.e. AlnGamIn1-n-mN and is at least partially of the second conductivity type, i.e. p-doped. The mesa structure 20 projects beyond the mask 4 in vertical direction, which is a direction perpendicular to the main extension plane of the semiconductor body 10 or the active region 3, respectively. For example, the height of the mesa structure 20, measured in vertical direction, is at most 50 nm or at most 20 nm and it projects beyond the mask 4 at most 10 nm. The shape of the mesa structure is mainly determined by the shape of the hole 40 in the mask 4.

In the position of FIG. 4, a contact layer 5 is applied onto the mesa structure 20 and onto the mask 4 in the area laterally next to the mesa structure 20. The contact layer 5 is formed contiguously without interruptions and covers the top side of the mesa structure 20 facing away from the active region 3, lateral sides of the mesa structure 20 running obliquely to its top side and the surface of the mask 4 facing away from the active region 3. The contact layer 5 is, for example, of ITO.

FIG. 5 shows the first exemplary embodiment of the semiconductor laser 100, which is, for example, produced with the previously described method. The semiconductor laser 100 is a VCSEL. In order to finalize the semiconductor laser 100, a Bragg mirror 7 and a contact element 6 have been applied to the contact layer 4. The Bragg mirror 7 covers the contact layer 5 in the area of the mesa structure 20. The contact element 6 is, for example, of Au and electrically contacts the contact layer 5 in an area laterally next to the mesa structure 20. A further contact element 8, which is also of metal, is applied on a side of the first region 1 facing away from the active region 3. The further contact 8 element may constitute a further mirror which, together with the Bragg mirror 7, forms a resonator for producing laser light.

During operation of the semiconductor laser 100, holes are injected from the contact element 6 into the contact layer 5 in the area laterally next to the mesa structure 20. The holes cannot directly enter into the second region 2 due to the dielectric mask 4. Therefore, the holes flow inside the contact layer 5 in lateral direction until they reach the mesa structure 20, into which they enter via the top side and/or via the lateral sides. From there, the holes diffuse inside the semiconductor body 10 towards the active region 3. In the active region 3, the holes recombine with electrons from the first region 1 and electromagnetic radiation is generated.

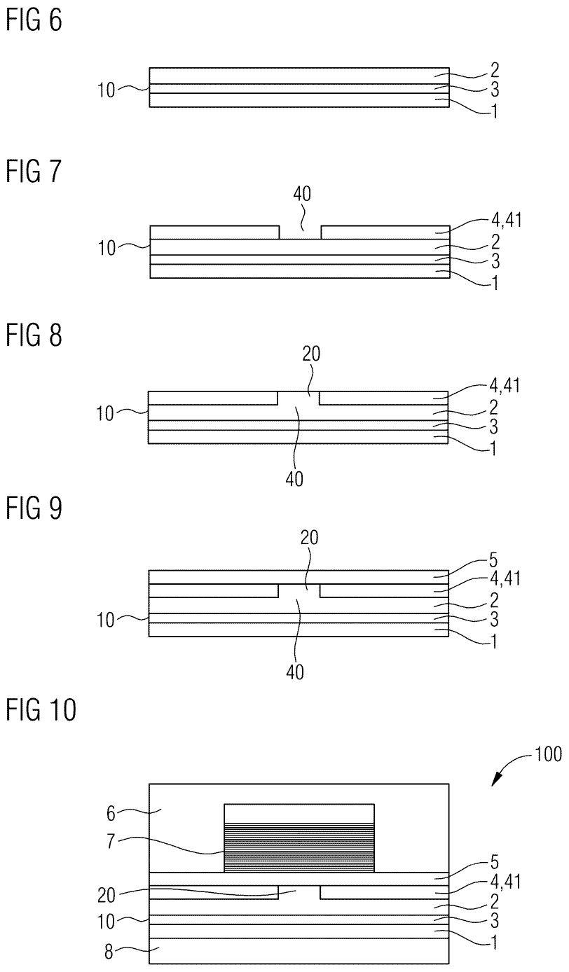

The second exemplary embodiment of the method is shown in FIGS. 6 to 9. The positions of FIGS. 6 and 7 are the same as those of FIGS. 1 and 2. In FIG. 8, a mesa structure 20 is epitaxially grown in the hole 40 of the mask 4, but only to such a height that the mesa structure 20 terminates flush with the mask 4 in vertical direction.

In FIG. 9, the contact layer 5 is applied to the mesa structure 20 and the mask 4. Due to the mesa structure 20 terminating flush with the mask 4, the contact layer 5 is substantially flat.

FIG. 10 shows the second exemplary embodiment of the semiconductor laser 100 which is, for example, produced with the method according to the second exemplary embodiment.

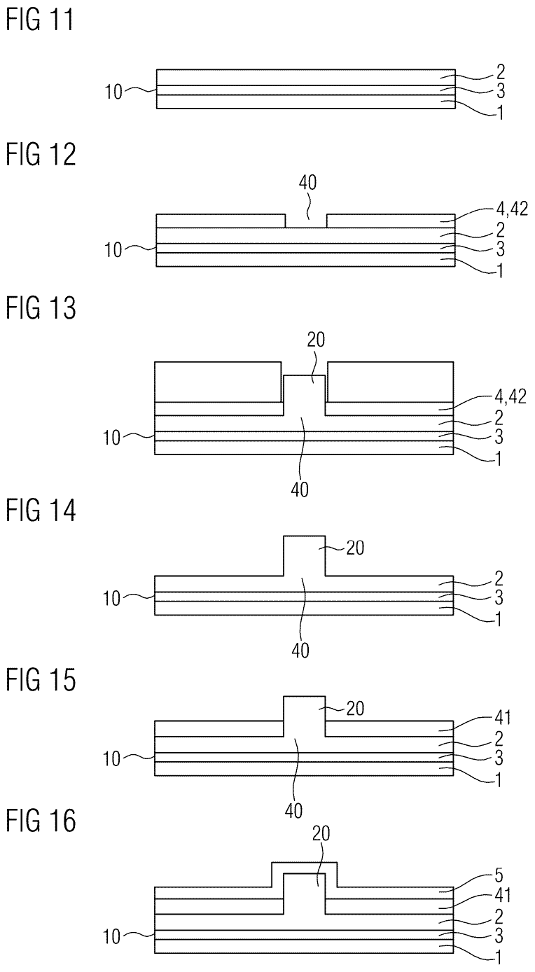

In the third exemplary embodiment of the method shown in FIGS. 11 to 16, the first position of FIG. 11 is the same as the first positions of previously described methods.

In FIG. 12, a mask 4 with a hole 40 is formed on the second region 2. In contrast to the previous exemplary embodiments, the mask 4 does not consist of SiO2 but of a 2-dimensional material, like graphene or hBN.

In FIG. 13, semiconductor material is deposited in the hole and on the side of the mask 4 facing away from the active region 3. In this case, the semiconductor material also deposits or grows on the mask 4. The probability of the semiconductor material growing on the mask 4 depends on the material of the mask 4. Instead of what is shown in FIG. 13, the 2-dimensional material of the mask 4 may also be such that the semiconductor material does not deposit or grow thereon, but only in the hole 40 (selective area growth).

In FIG. 14, the mask 4 together with the semiconductor material thereon is removed. Due to the 2-dimensional material used for the mask 4, this removal is particularly easy.

Then, in the position of FIG. 15, a dielectric layer 41 is applied in the area laterally next to the mesa structure 20. The dielectric layer 41 is, for example, of SiO2.

In the position of FIG. 16, the contact layer 5 is applied to the mesa structure 20 and the dielectric layer 41.

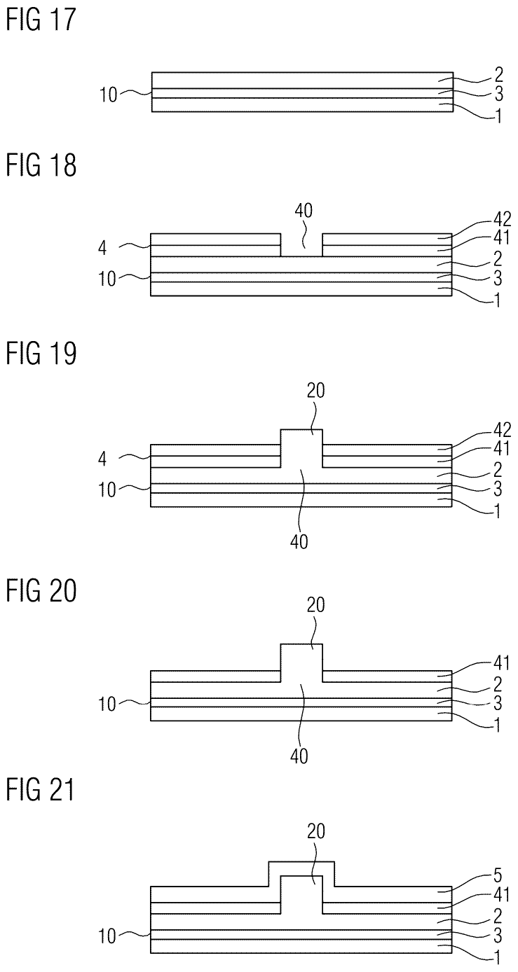

FIGS. 17 to 21 show a fourth exemplary embodiment of the method. The first position of FIG. 17 is the same as in the previous exemplary embodiments.

In the position of FIG. 18, a mask 4 with a hole 40 is formed on the second region 2. In contrast to the previous exemplary embodiments, the mask 4 now comprises or consist of a dielectric layer 41 and a layer 42 of a 2-dimensional material. The dielectric layer 41 is located between the layer 42 and the second region 2.

After having grown the mesa structure 20 (see FIG. 19), the layer 42 of the 2-dimensional material is removed, if applicable together with any semiconductor material thereon, and only the dielectric layer 41 is maintained (see FIG. 20). Then, a contact layer 5 is applied to the mesa structure 20 and the dielectric layer 41 (see FIG. 21).

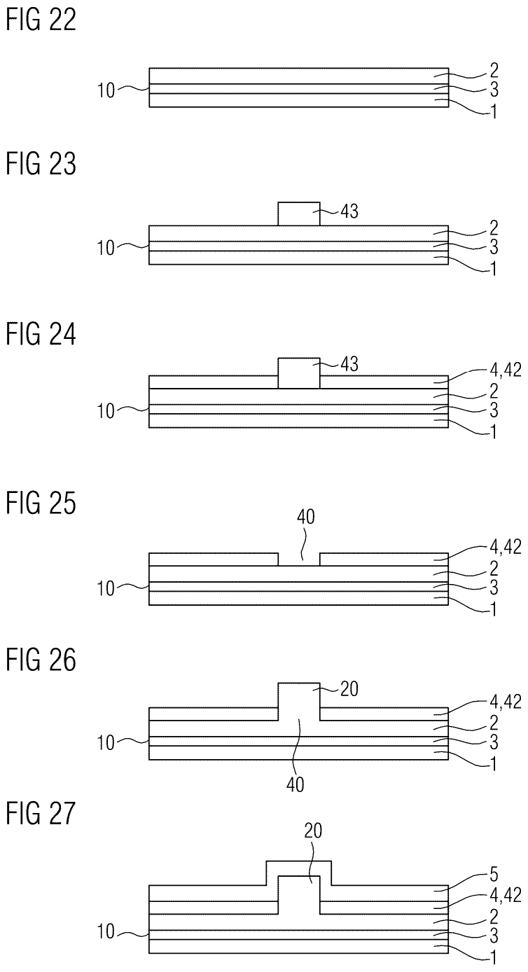

The fifth exemplary embodiment of the method of FIGS. 22 to 27 starts with the same first position as the previous exemplary embodiments.

In FIG. 23, a dummy element 43, e.g. of a dielectric material, like SiO2, is arranged on the second region 2 of the semiconductor body 10 in the area where the mesa structure shall be produced.

Then, a mask 4 is applied to the second region 2. The dummy element 43 protects the second region 2 from being covered by the mask 4 (see FIG. 24).

In FIG. 25, the dummy element 43 is removed, so that a hole 40 remains in the mask 4. The surface of the second region 2 is exposed in the hole 40. Due to the usage of the dummy element 43, a lithographic process for producing the hole 40 is not necessary.

In FIG. 26, the mesa structure 20 is grown in the hole 40, e.g. by selective area growth.

In FIG. 27, a contact layer 5 is applied to the mesa structure 20 and the mask 4.

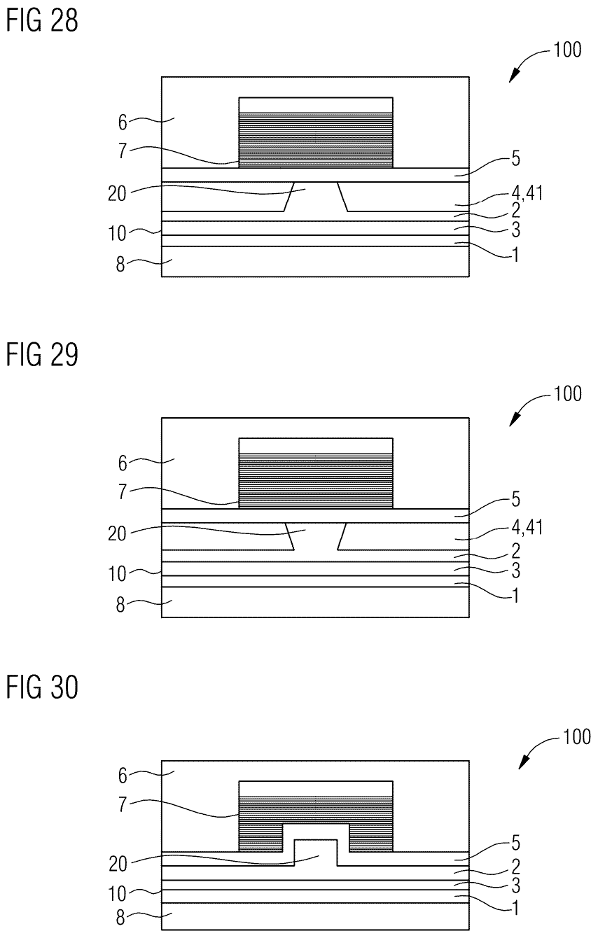

FIG. 28 shows a further exemplary embodiment of the semiconductor laser 100. Different to the exemplary embodiments of FIGS. 5 and 10, the mesa structure 20 now tapers in vertical direction away from the active region 3. Such a shape can be achieved by a corresponding shape of the mask 4.

In the exemplary embodiment of FIG. 29, the mesa structure 20 tapers in vertical direction towards the active region 3.

FIG. 30 shows an exemplary embodiment of the semiconductor laser 100, in which the contact layer 5 is applied directly to the second region 2 in the area laterally next to the mesa structure 20. This is possible, for example, when the top side has a higher doping concentration than the surface of the second region 2. For example, when the surface of the second region 2 is formed by an undoped spacer layer or an electron blocking layer, the electrical contact between the second region 2 and the contact layer 5 is so bad that no dielectric material is needed in between them. The mask 4 used for producing the semiconductor laser 1 could therefore have been completely removed.

The invention described herein is not limited by the description in conjunction with the exemplary embodiments. Rather, the invention comprises any new feature as well as any combination of features, particularly including any combination of features in the patent claims, even if said feature or said combination per se is not explicitly stated in the patent claims or exemplary embodiments.

1.-19. (canceled)

20. A method for producing a semiconductor laser, the method comprising:
providing a semiconductor body having a first region of a first conductivity type, a second region and an active region for producing electromagnetic radiation arranged between the first and the second region;
forming a mask on the second region;
forming a hole in the mask so that a surface of the second region is exposed; and
growing a mesa structure of a semiconductor material on the exposed surface of the second region in the hole of the mask,
wherein the mesa structure is at least partially of a second conductivity type being different from the first conductivity type, and
wherein a height of the mesa structure is at most 50 nm.

21. The method according to claim 20, further comprising, after growing the mesa structure, arranging a contact layer on the mesa structure, arranging a contact element on the contact layer, and arranging a Bragg-mirror on the mesa structure, wherein the semiconductor laser is a VCSEL.

22. The method according to claim 20, wherein a selective area growth is used for growing the mesa structure so that less and/or polycrystalline semiconductor material is grown on the mask laterally next to the hole than in the hole.

23. The method according to claim 20, further comprising:
while growing the mesa structure, depositing or growing the semiconductor material on the mask laterally next to the hole; and
removing the semiconductor material on the mask laterally next to the hole.

24. The method according to claim 21, wherein a top side of the mesa structure facing away from the active region has a higher doping concentration than the surface of the second region facing away from the active region in an area laterally next to the mesa structure.

25. The method according to claim 24, wherein the contact layer is applied directly onto the second region in the area laterally next to the mesa structure.

26. The method according to claim 20, wherein the exposed surface of the second region is an undoped spacer layer.

27. The method according to claim 20, wherein the exposed surface of the second region is a blocking layer for blocking charge carriers of the first type.

28. The method according to claim 20, wherein the exposed surface of the second region is a highly doped layer having a doping concentration of at least 1019 cm−3.

29. The method according to claim 20,
wherein the mask comprises a dielectric layer, and
wherein the dielectric layer remains in the final semiconductor laser in order to suppress a current flow in the second region laterally next to the mesa structure.

30. The method according to claim 20, further comprising removing the mask after a growth of the mesa structure.

31. The method according to claim 20,
wherein the mask comprises a layer of a 2-dimensional material, and
wherein the layer of the 2-dimensional material is removed after the mesa structure has been grown.

32. The method according to claim 20, wherein the mesa structure is grown such that it vertically projects beyond the mask.

33. The method according to claim 20, wherein the mesa structure is grown such that it terminates flush with the mask in vertical direction.

34. The method according to claim 20, wherein the mesa structure is grown such that it tapers in a vertical direction away from the active region.

35. The method according to claim 20, wherein the mesa structure is grown such that it tapers in a vertical direction towards the active region.

36. A semiconductor laser comprising:
a semiconductor body having a first region of a first conductivity type, a second region and an active region configured to generate electromagnetic radiation, the active region arranged between the first and second regions; and
a mesa structure of a semiconductor material grown on the second region, the mesa structure being free of traces of an etching process,
wherein the mesa structure is at least partially of a second conductivity type different from the first conductivity type, and
wherein a height of the mesa structure is at most 50 nm.

37. The semiconductor laser according to claim 36, further comprising:
a contact layer arranged on the mesa structure in an area laterally next to the mesa structure and in electrical contact with the mesa structure;
a contact element arranged on the contact layer and in electrical contact with the contact layer; and
a Bragg-mirror arranged on the mesa structure,
wherein the semiconductor laser is a VCSEL.
